(19) United States
(12) Patent Application Publication
(10) Pub. No.: US 2016/0254793 A1
(43) Pub. Date: Sep. 1, 2016

(54) CLOCK AND DATA DRIVERS WITH ENHANCED TRANSCONDUCTANCE AND SUPPRESSED OUTPUT COMMON-MODE

(71) Applicants: Wenjun SU, San Diego, CA (US); Guangming YIN, San Diego, CA (US); Quanqing ZHU, San Diego, CA (US); QUALCOMM INCORPORATED, San Diego, CA (US)

(72) Inventors: Wenjun SU, San Diego, CA (US); Guangming YIN, Corona Del Mar, CA (US); Quanqing ZHU, Shanghai (CN)

(21) Appl. No.: 15/029,777

(22) PCT Filed: Nov. 5, 2014
(86) PCT No.: PCT/CN2014/090318

§ 371 Date: Apr. 15, 2016

(30) Foreign Application Priority Data
Nov. 7, 2013 (CN) PCT/CN2013/086674

(51) Int. Cl. H03F 3/45; H03K 5/12

(52) U.S. Cl. CPC H03F 3/45762; H03K 5/12; H03F 2203/45288; H03F 2200/72

(57) ABSTRACT

Methods, apparatus, and means for maintaining a low output common-mode voltage in a driver are provided. One example apparatus includes a first differential amplifier stage configured to provide a differential output for the apparatus; and a second differential amplifier stage configured to drive the first differential amplifier stage, the second differential amplifier stage including a pair of pre-driver amplifiers, a pair of n-stage circuits, and an input skew averaging circuit, wherein each of the pair of n-stage units is split into two half blocks. The input skew averaging circuit is configured to suppress the output common-mode voltage by driving the blocks with complementary digital inputs to average out a skew in a gate-to-source voltage of the pair of n-stage circuits. For certain aspects, two feed-forward capacitors may be added to enhance the transconductance and operating speed of main transistors of the first differential amplifier stage.

### CROSS-REFERENCE TO RELATED APPLICATION(S)

This application claims priority to International Patent Application No. PCT/CN2013/086674, filed on Nov. 7, 2013, which is herein incorporated by reference in its entirety.

### BACKGROUND

1. Field

This invention relates to clock and data drivers, and more specifically, to a driver that is configured to provide low output common-mode voltage and enhanced transconductance (gm) and speed.

2. Background

In a high-speed data communication system, it is often desirable to deliver the data and clock signal using compact MOSFETs with small common-mode variation. The compact MOSFETs provide good impedance matching, while large MOSFETs usually contribute undesired low nonlinear resistance due to large parasitic components. Further, since high output common-mode variation induces strong coupling and interference between different channels and degrades overall system performance, it is desirable to maintain small output common-mode variation.

FIG. 1A shows one example of a conventional clock and data driver 100 with inductors L1 and L2, which play a key role in extending the driver bandwidth. FIG. 1B shows another example of a conventional clock and data driver 110 with a cascode structure that provides high bandwidth, but with less headroom. Due to the heavy off-chip loading (normally 50 ohms (Ω) for single-ended or 100 Ω0 for differential), the size of transistors M1 and M2 may most likely be large enough in order to deliver enough signal power to the load. However, large size MOSFETs also come with a small nonlinear resistance (R_{DS}) and can be even smaller than the load resistance at high frequencies, which will make it difficult to match the output load. Furthermore, the output common-mode voltage (0.5*(Vₒᵤₜₚ+Vₒᵤₜₙ) in FIG. 1A and FIG. 1B) is normally high due to the mismatch between the transistors and the non-ideality of tail current I_{bias}.

### SUMMARY

Embodiments of the present invention include apparatus, method, and means to provide a high-speed driver with low output common-mode.

In one embodiment, an apparatus to provide low output common-mode voltage is disclosed. The apparatus includes a first differential amplifier stage configured to provide a differential output for the apparatus; and a second differential amplifier stage configured to drive the first differential amplifier stage, the second differential amplifier stage including a pair of pre-driver amplifiers, a pair of n-stage circuits, and an input skew averaging circuit, wherein each of the pair of n-stage circuits is split into two half blocks. The input skew averaging circuit is configured to suppress the output common-mode voltage by driving the two half blocks with complementary digital input to average out a skew in the pair of n-stage circuits.

For some embodiments, each of the pair of n-stage circuits includes an input transistor configuration and an inverter-based logic gate configured to drive the input transistor configuration. The input skew averaging circuit may include a pair of complementary transistor configurations, each configured to mirror one of the input transistor configurations in the pair of n-stage circuits; and a pair of inverter-based logic gates configured to generate complementary inputs for the pair of complementary transistor configurations to average out the skew in gate-to-source voltages of the input transistor configurations. The input transistor configuration may include a PMOS transistor and an NMOS transistor. In this case, the size of the PMOS transistor in the input transistor configuration may be configured to be relatively small compared to the size of the NMOS transistor.

For some embodiments, the apparatus may further include a transconductance enhancement circuit configured with a pair of capacitors to speed up switching transitions of the first differential amplifier stage.

For some embodiments, the first differential amplifier stage includes a pair of main driver transistors configured as a common gate amplifier and wherein the second differential amplifier stage comprises a pair of input transistors configured as a common source amplifier in cascode with the common gate amplifier. In this case, the apparatus may further include a current sink circuit configured to sink a small leakage current from the first differential amplifier stage to prevent the pair of main driver transistors in the first differential amplifier stage from completely switching off into a cut-off mode. In some embodiments, the current sink circuit includes a pair of NMOS transistors, wherein gates of the NMOS transistors are coupled to outputs of the pair of pre-driver amplifiers, wherein drains of the NMOS transistors are coupled to differential inputs of the common gate amplifier, and wherein sources of the NMOS transistors are coupled to electrical ground. The apparatus may further include a pair of bias transistors configured in a cascode configuration to sink a bias current source and provide a bias voltage to a common gate node of the pair of main driver transistors in the common gate amplifier. For some embodiments, the apparatus may further include a pair of capacitors coupled to gates of the pair of main driver transistors and to gates of the pair of input transistors. Alternatively or additionally, the apparatus may further include a pair of capacitors coupled to gates of the pair of main driver transistors and to inputs of the two half blocks.

For some embodiments, each of the pair of pre-driver amplifiers includes a programmable inverter-based logic device configured to control rising and falling edges of a gate-to-source voltage of each of the pair of n-stage circuits. In this case, the programmable inverter-based logic device may include a PMOS transistor and a plurality of parallel NMOS transistors, each NMOS transistor coupled to a switch to allow each NMOS transistor to be programmably switched in.

In another embodiment, a method for suppressing output common-mode voltage in a driver is disclosed. The method generally includes driving a first differential amplifier stage using a second differential amplifier stage, which includes a pair of pre-driver amplifiers, a pair of n-stage circuits, and an input skew averaging circuit, wherein each of the pair of n-stage circuits is split into two half blocks; and performing input skew averaging to suppress the output common-mode voltage by driving the two half blocks with complementary digital inputs to average out a first skew in gate-to-source voltages of the pair of n-stage circuits.

In another embodiment, an apparatus for suppressing output common-mode voltage in a driver is disclosed. The apparatus generally includes means for driving a differential amplifier stage, wherein the means for driving includes a pre-driver amplifier and a pair of n-stage circuits, wherein each of the pair of n-stage circuits is split into two half blocks; and means for performing input skew averaging to suppress the output common-mode voltage by driving the two half blocks with complementary digital inputs to average out a first skew in gate-to-source voltages of the pair of n-stage circuits.

Other features and advantages of the present invention should be apparent from the present description which illustrates, by way of example, aspects of the invention.

### BRIEF DESCRIPTION OF THE DRAWINGS

The details of the present invention, both as to its structure and operation, may be gleaned in part by study of the appended further drawings, in which like reference numerals refer to like parts, and in which:

FIG. 1A is a schematic diagram of an example conventional clock and data driver with two inductors;

FIG. 1B is a schematic diagram of an example conventional clock and data driver with a cascode structure;

FIG. 2 is a block diagram of a driver (e.g., clock or data driver) configured to provide low output common-mode voltage and enhanced transconductance and speed, in accordance with one embodiment of the present invention;

FIG. 3A is a schematic diagram showing an example implementation of n-stage circuit 222A of FIG. 2, in accordance with one embodiment of the present invention;

FIG. 3B is a schematic diagram showing an example implementation of n-stage circuit 222B of FIG. 2, in accordance with one embodiment of the present invention;

FIG. 4 is a schematic diagram showing an example implementation of the input skew averaging circuit, in accordance with one embodiment of the present invention;

FIG. 5 is an example timing diagram illustrating an input skew averaging or cancelling process, in accordance with one embodiment of the present invention;

FIG. 6 is a schematic diagram illustrating an example driver depicted in parts in connection with FIGS. 2 through 5;

FIG. 7 is an example timing diagram illustrating node transient voltage waveforms associated with the pre-distortion/pre-emphasis generated by the insertion of feed-forward capacitors C1 and C2, in accordance with one embodiment of the present invention;

FIG. 8 is a schematic diagram illustrating an example pre-driver amplifier configured as a multi-transistor inverter with a PMOS transistor and a plurality of programmable NMOS transistors, in accordance with one embodiment of the present invention; and

FIG. 9 is a flow diagram of example operations for suppressing an output common-mode voltage in a driver, in accordance with one embodiment of the present invention.

### DETAILED DESCRIPTION

As described above, conventional clock and data drivers are typically designed to be large enough in order to deliver enough signal power to the load. However, large size MOSFETs also come with a small nonlinear resistance (R_{DS}) that can be even smaller than the load resistance at high frequencies, which will make it difficult to match the output load. By feeding forward a small amount of input to the common-gate bias node, an equivalent transconductance boost circuit can be realized, and hence, a relatively small-sized transistor may be sufficient to provide expected output power. The disadvantages of the conventional clock and data drivers also include relatively high output common-mode voltage due to the mismatch between the transistors and the non-ideality of the tail current. Further, any waveform skew and rising/falling edge mismatch between the inputs will enlarge the output common-mode voltage. Experiments have shown that the output common-mode voltage almost doubles with 10 Gbps input signal and with as little as 0.1 ps skew.

Certain embodiments as described herein offer a driver configured to provide relatively low output common-mode voltage and enhanced transconductance (gm) and speed. After reading this description, it will become apparent how to implement the invention in various implementations and applications. Although various implementations of the present invention will be described herein, it is understood that these implementations are presented by way of example only, and not limitation. As such, this detailed description of various implementations should not be construed to limit the scope or breadth of the present invention.

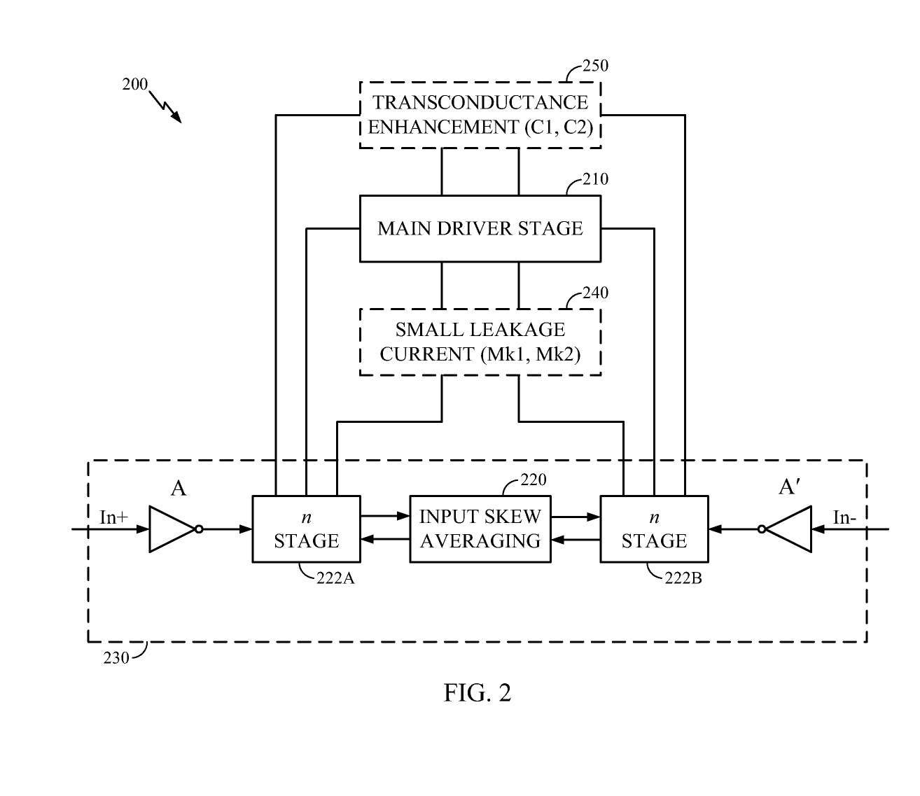

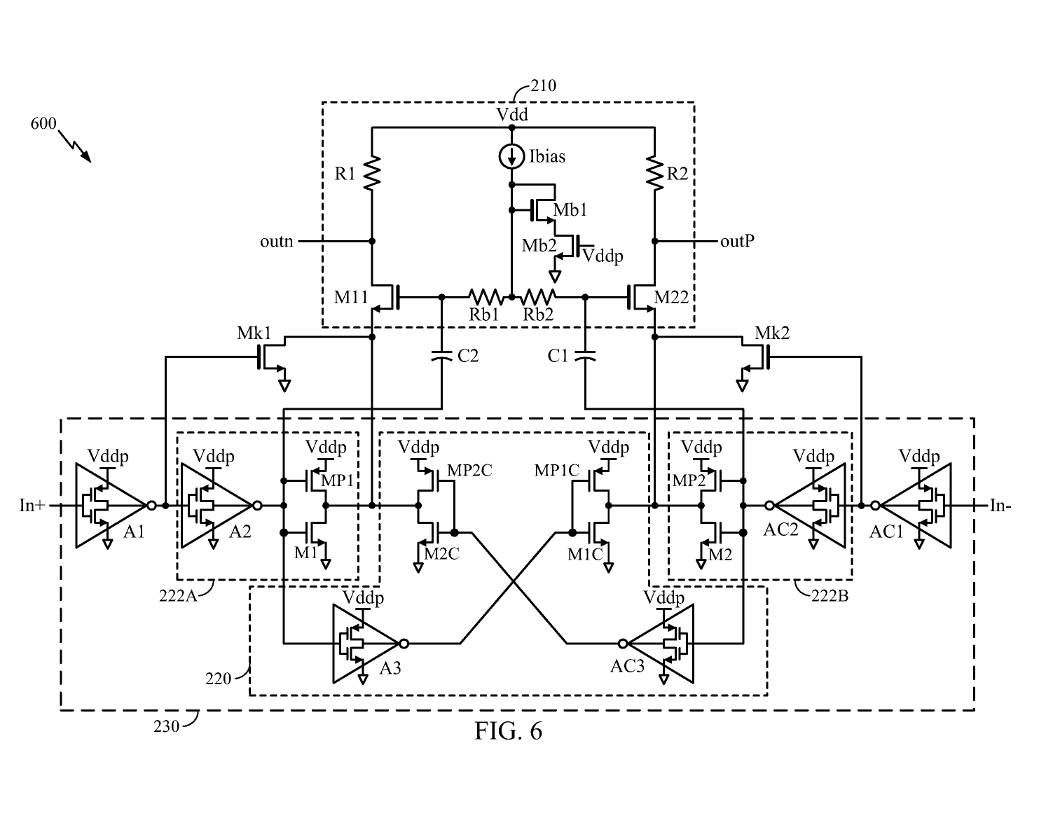

FIG. 2 is a block diagram of a driver 200 (e.g., clock or data driver) configured to provide low output common-mode voltage and enhanced transconductance and speed. The driver 200 uses a differential amplifier configuration that includes at least a pre-driver stage 230 and a main driver stage 210. The pre-driver stage 230 includes a pair of amplifiers A and A′; a pair of n-stage circuits 222A, 222B; and an input skew averaging circuit 220, which provides low output common-mode voltage by splitting the pair of n-stage circuits 222A, 222B into two equal half blocks formed as the input skew averaging circuit 220. Each of the n-stage circuits 222A, 222B is driven with complementary digital input to average or cancel out the skew in the gate-to-source voltage of the n-stage circuits 222A, 222B. For some embodiments, a small current (e.g., with a typical value of a few μA) may be provided to transistors in the main driver stage 210 by current sink circuit 240 to prevent the main driver transistors from completely switching off in an effort to prevent lag in the transistor startup and to provide speed enhancement. Amplifiers A and A′ in the pre-driver stage 230 can be programmed to control the rising/falling edges and to further provide low output common-mode voltage. Transconductance enhancement circuit 250 may optionally be provided by a pair of capacitors (e.g., C1 and C2 in FIG. 6) that feed forward the digital edge transition in the pre-driver stage 230 to the gates of the transistors in the main driver stage 210.

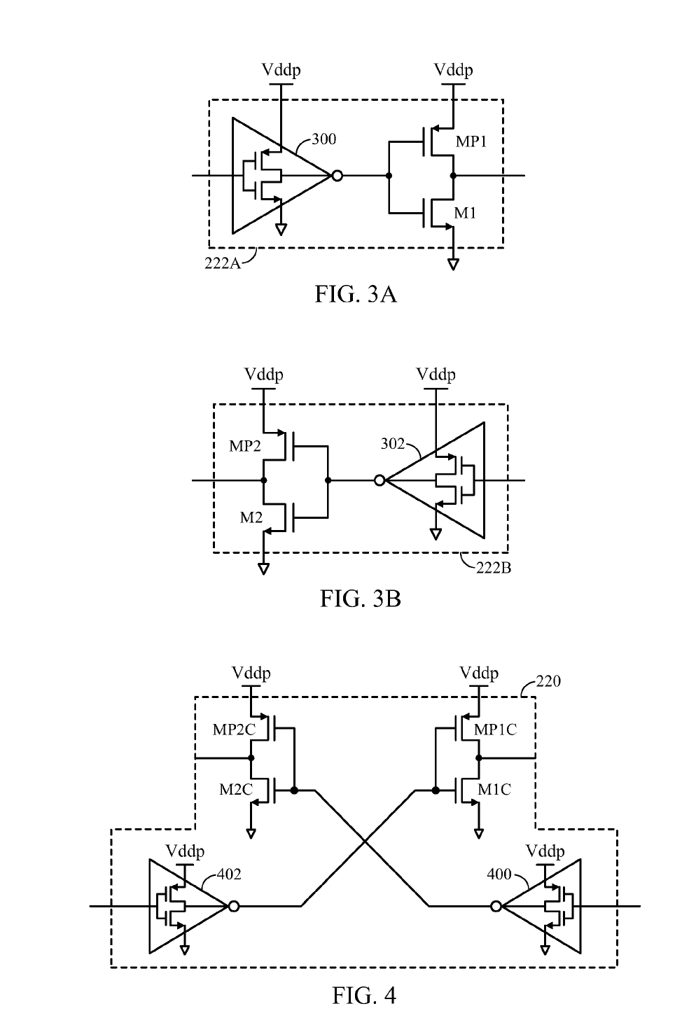

FIG. 3A and FIG. 3B are schematic diagrams showing example implementations of n-stage circuit 222A and n-stage circuit 222B, respectively, in accordance with embodiments of the present invention. N-stage circuit 222A includes an inverter-based logic gate 300, which may drive a two-transistor inverter configuration Ml, MP1. N-stage circuit 222B includes an inverter-based logic gate 302, which may drive a two-transistor inverter configuration M2, MP2. In one embodiment, M1 and M2 are NMOS transistors, while MP1 and MP2 are PMOS transistors. Because the current in the transistors M11/M22 of the main driver stage 210 (see FIG. 6) is re-used in the NMOS transistors (i.e., M1/M2 shown in FIG. 3A and FIG. 3B and M1C/M2C shown in FIG. 4), the size of the PMOS transistors may be designed to be relatively small compared to the NMOS transistors. For example, the NMOS M1 and M2 width-to-channel-length ratio may be set to 100, while the same ratio for the corresponding PMOS MP1 and MP2 may be about 2. The role for the PMOS transistors in this case is to quickly charge the source terminals of the main transistors M11/M22 and, in turn, speed up the low-to-high transition of the output (outn/outp). However, this is not necessary for most applications because the outputs are already pre-charged to the positive supply voltage (V_{dd}) through resistors R1 and R2 (see FIG. 6) and can make sufficiently fast transitions. In another embodiment, PMOS transistors MP1 and MP2 are optional and are thus eliminated. Alternatively, in some applications where faster low-to-high transition than high-to-low transition is desired, the PMOS transistors are suitable devices to meet that goal.

As stated above, the pair of n-stage circuits 222A, 222B is split into two equal half blocks formed as the input skew averaging circuit 220. FIG. 4 is a detailed schematic diagram showing the input skew averaging circuit 220 in accordance with one embodiment of the present invention. The input skew averaging circuit 220 includes an inverter-based logic gate 400 whose output drives the common gate input of a two-transistor inverter configuration M2C, MP2C. The inverter-based logic gate 400 mirrors the logic gate 300, and the two-transistor inverter configuration M2C, MP2C mirrors the two-transistor inverter configuration M1, MP1 shown in FIG. 3A. The input skew averaging circuit 220 also includes an inverter-based logic gate 402 whose output drives the common gate input of a two-transistor inverter configuration M1C, MP1C. The inverter-based logic gate 402 mirrors the logic gate 302 and the two-transistor inverter configuration M1C, MP1C mirrors the two-transistor inverter configuration M2, MP2 shown in FIG. 3B. The outputs of these mirrored configurations are combined. In one embodiment, PMOS transistors MP1C and MP2C are optional and are thus eliminated. By splitting the n-stage circuits 222A, 222B into two equal half blocks formed as the input skew averaging circuit 220 shown in FIG. 4, the n-stage circuits 222A, 222B are driven with complementary digital input to average out or remove the skew in the gate-to-source voltage of the n-stage circuits 222A, 222B.

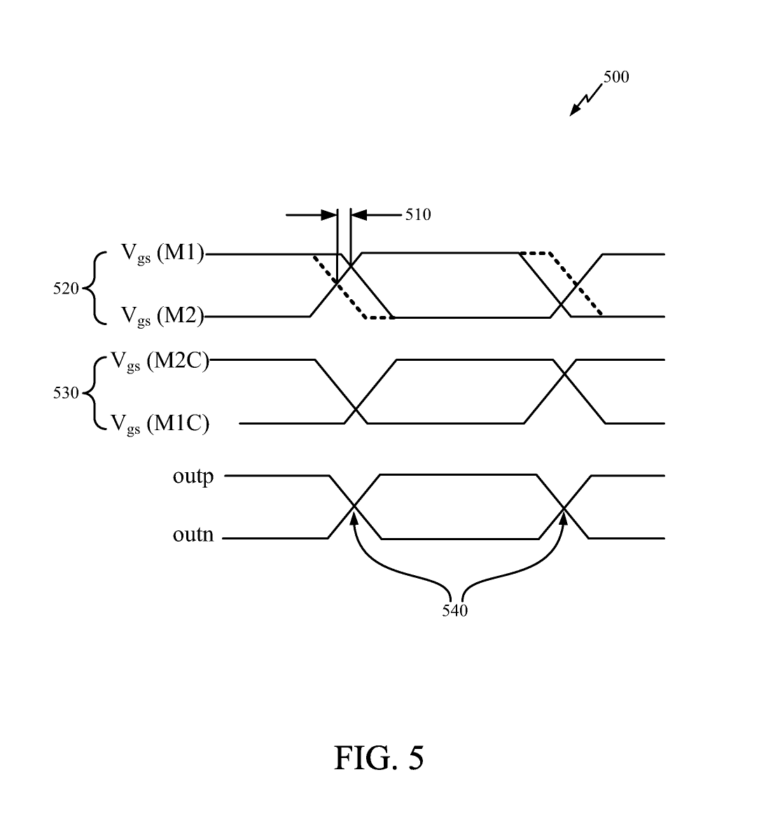

FIG. 5 shows an example timing diagram 500 illustrating an input skew averaging or cancelling process according to one embodiment of the present invention. In FIG. 5, the upper differential signal pair 520 shows the gate-to-source voltages (V_{gs}) of differential output stage transistors M1 and M2. In the illustrated embodiment, the input signal to the gates of M1 and M2 includes a skew (a mismatch between transistors M1 and M2 causes the skew to worsen) and causes a waveform skew 510 here which would result in a high output common-mode voltage. By providing complementary digital inputs to drive the n-stage circuits 222A, 222B using mirror transistors M1C and M2C, the waveform skew 510 can be averaged out or substantially cancelled. The middle differential signal pair 530 shows the gate-to-source voltages of transistors M1C and M2C, which include the same waveform skew but with a reversed polarity. After the two-half parts (i.e., M1/M2C and M2/M1C) are re-combined at the drains of Ml/M2C and M2/M1C (or the sources of main driver transistors M11, M22), the waveform skew 510 is substantially cancelled (see waveform intersections 540 in the differential output signal pair). Experiments have shown that the output common-mode voltage almost doubles with 10 Gbps input signal and with as little as 0.1 ps skew.

FIG. 6 is a schematic diagram of an example driver 600, which was described above in parts in connection with FIGS. 2-5. Transistors M1 and M2 (as well as transistors M2C and M1C) form a common source differential amplifier (here, a transconductance amplifier), which is an input stage to a cascode differential amplifier. This input stage is configured to drive a common gate differential amplifier (formed by transistors M11 and M22), which is an output stage of the cascode differential amplifier, which functions as a driver.

In the illustrated embodiment of FIG. 6, the differential input of the driver 600 (i.e., the input of the pre-driver stage 230) is a digital logic signal, and thus, the current-mode logic (CML) level shift block is not needed and has been removed from the pre-driver stage 230. Since transistors M1/M2/M1C/M2C can work in a linear region, the headroom limitation can be relaxed. Also, if there is no headroom restriction (normally with high V_{dd}), the size of transistors M1/M2/M1C/M2C and Mb2 can be reduced until their V_{ds} is high enough to ensure that the transistors are all in the saturation region. This will increase the driver output impedance (looking into the drains of M11/M22) from about several tens of Ω to several hundreds of Ω and hence make the output impedance matching much easier. Further, pre-driver amplifiers A1 to A3 and AC1 to AC3 in the pre-driver stage 230 may be implemented with inverter-based logic gates (e.g., CMOS inverters).

FIG. 6 also shows the main driver transistors M11 and M22 whose large size can be reduced with the help of feed-forward capacitors C1 and C2 (normally very small, and less than 20 fF for a 10 Gbps application) by applying a small portion of the opposite polarity signal with respect to the sources of transistors M11 and M22 applied to their gates via both C1 and C2 during the high-speed transition period. By adding C1 and C2, the real-time gate-to-source voltage (V_{gs}) of transistors M11/M22 during signal transition is boosted. This not only speeds up the M11/M22 switching transition, but also helps to steer more current to the output load during the transition. Hence, both M11 and M22 can be implemented with a reduced size for the same output signal. Because both C1 and C2 are small, the loading effect to A3 and AC3 can be ignored.

Further, the addition of the feed-forward capacitors C1 and C2 provides an added benefit of improving the linearity of the amplifiers in the driver 600 because it creates pre-distortion (wireless case) or pre-emphasis (wireline case), which alters the amplitude-versus-frequency characteristics of a signal to reduce adverse effects of the channel (air for wireless, and PCB trace for wireline). The high-frequency signal components are emphasized to compensate the high frequency loss of the channel and, hence, produce a more equal modulation index for the transmitted frequency spectrum, and therefore a better signal-to-noise ratio (SNR) for the entire frequency range. The value of either or both capacitors C1 and C2 may be varied with switched capacitors to provide the desired programmable emphasis. In one embodiment, the value can be varied between 10 and 20 fF.

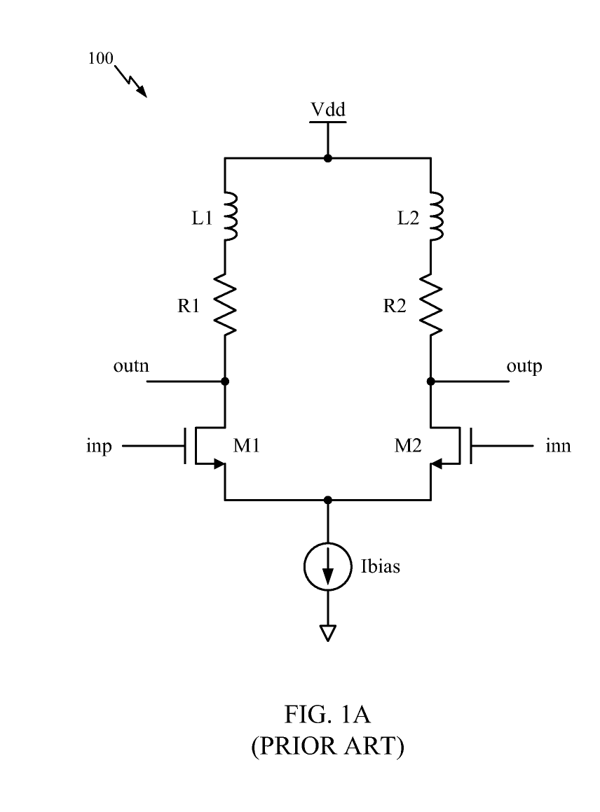

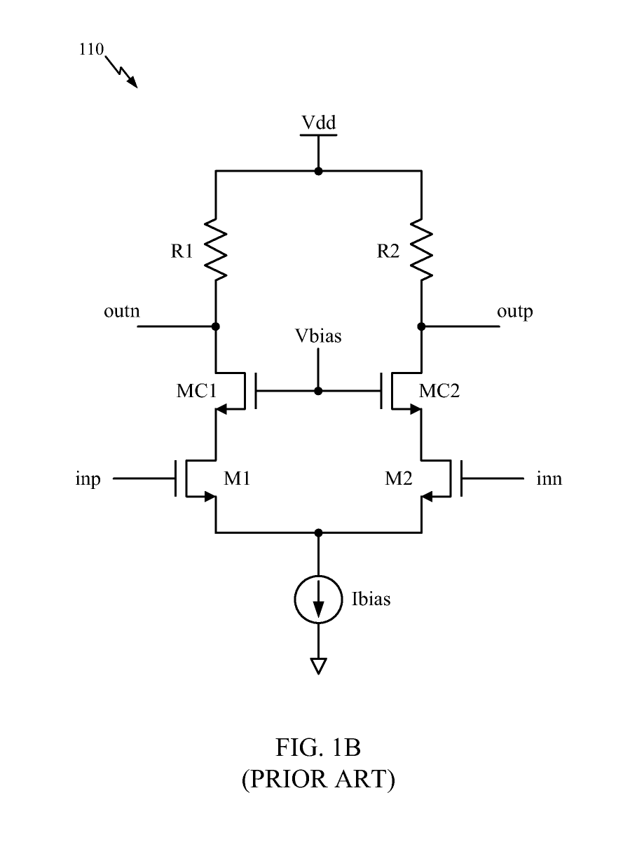

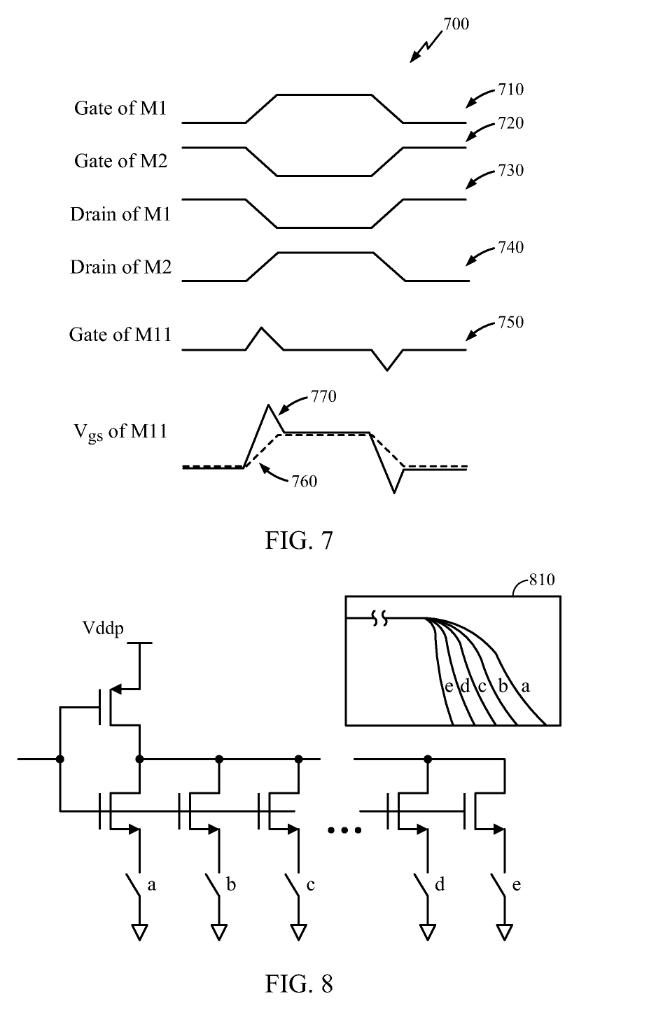

FIG. 7 is an example timing diagram 700 illustrating node transient voltage waveforms associated with the pre-distortion/pre-emphasis generated by the insertion of feed-forward capacitors C1 and C2. The timing diagrams 710 and 720 show transient voltage waveforms at the gates of transistors M1 and M2, respectively, while the timing diagrams 730 and 740 show transient voltage waveforms at the drains of transistors M1 and M2, respectively. The reverse polarity of the transient voltage waveforms between the gates and the drains show that transistors M1 and M2 act as inverters. Thus, the gate-to-source voltage (V_{gs}) of main transistor M11 without the feed-forward capacitor C2 (wherein the gate of M11 is connected to the gate of M1 and the source of M11 is connected to the drain of M1) would have a transient voltage waveform as shown in the dotted timing diagram 760. However, with feed-forward capacitor C2 connected between the gates of transistors M1 and M11 which acts as a high-pass filter, the transient voltage waveform at the gate of transistor M11 is as shown in the timing diagram 750 with spikes at the transitions of the waveform for the gate of transistor M1 shown in the timing diagram 710. The timing diagram 770 shows the gate-to-source voltage (V_{gs}) of main transistor M11 with boosts at the transitions. Hence, the insertion of feed-forward capacitors can be used to implement an emphasis effect including pre-emphasis and post-emphasis. This boost not only speeds up the switching transition of the main transistor M11 (the same boost is provided by C1 for M22), but also helps to steer more current to the output load during the transition. Hence, both M11 and M22 can be implemented with a reduced size for the same output signal compared to the conventional drivers shown in FIG. 1A and FIG. 1B.

Referring back to FIG. 2, it was stated that amplifiers A and A′ in the pre-driver stage 230 can be programmed to control the rising/falling edges and to further provide low output common-mode voltage. In the context of FIG. 6, amplifiers A and A′ include pre-driver amplifiers A1, A2, A3, AC1, AC2, and AC3. For resistive loads, a minimizing condition for the output common-mode voltage is the differential output crossing point being in the middle with equal rising and falling edges. To meet this minimizing condition, the pre-driver amplifiers can be configured as programmable amplifiers that can control the rising and falling edges.

For example, in one embodiment shown in FIG. 8, a pre-driver amplifier is configured as a multi-transistor inverter 800 with a PMOS transistor and a plurality of parallel NMOS transistors that can be switched in (with switches ‘a’ through ‘e’ and assuming switch ‘a’ is turned on first and remains on when switch ‘b’ is turned on, and so on) to control the rising/falling edges. The inset FIG. 810 shows one example of falling edge variations according to the addition of NMOS transistors switched in with switches ‘a’ through ‘e’. In another embodiment, the rising/falling edge can be adjusted by changing the power supply voltage V_{ddp} of the pre-driver amplifiers. For example, V_{ddp} can be adjusted to be 0.9 V instead of 1.0 V. The principle is the same as matching the rising/falling edge since varying V_{ddp} induces the rising/falling edge changes.

Referring again to FIG. 6, MOSFETs Mk1 and Mk2 (current sink circuit 240 in FIG. 2) are added as a small current sink in an effort to ensure that the main switching transistors M11, M22 operate with nonzero current during switching transitions. That is, the small leakage current sunk by small NMOS transistors Mk1 and Mk2 prevents the main driver transistors from completely switching off into a cut-off mode. In other words, transistors Mk1 and Mk2 are provided to maintain high-speed transition for the common-gate amplifiers formed with transistors M11 and M22. Alternatively, Mk1 and Mk2 can be configured as a small DC current sink, but with additional bias circuitry.

In FIG. 6, the main driver stage 210 further includes transistors Mb1 and Mb2 in a cascode configuration to provide a well-defined bias current to the gates of transistors M11 and M22. In one embodiment, to provide this well-defined bias current, the size ratio between transistors Mb1 and M11 should be equal to the ratio between transistors Mb2 and M1+M2C, while the size ratio between transistors Mb1 and M22 should be equal to the ratio between transistors Mb2 and M2+M1C.

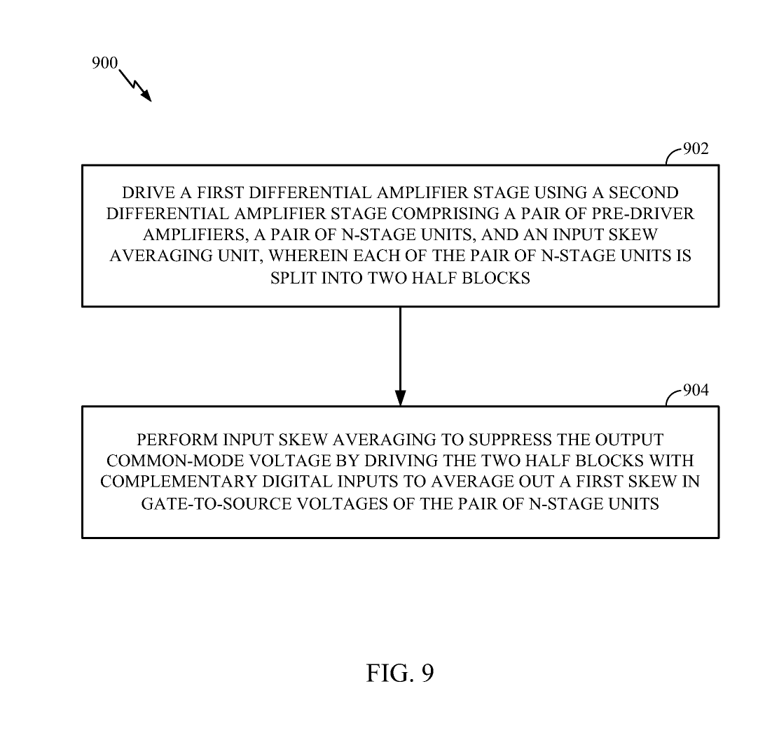

FIG. 9 is a flow diagram of example operations 900 for suppressing an output common-mode voltage in a driver, in accordance with one embodiment of the present invention. The operations 900 may begin, at 902, by driving a common gate input of a first differential amplifier stage using a second differential amplifier stage. The second differential amplifier stage includes a pre-driver amplifier, a pair of n-stage circuits, and an input skew averaging circuit, and each of the pair of n-stage circuits (i.e., each re-stage circuit) is split into two half blocks.

At 904, input skew averaging is performed to suppress the output common-mode voltage by driving the two half blocks with complementary digital inputs to average out a first skew in gate-to-source voltages of the pair of n-stage circuits. For some embodiments, performing input skew averaging at 904 may also involve combining outputs of mirror transistors, which mirror transistors in the pair of n-stage circuits, with outputs of the pair of n-stage circuits to remove (or at least reduce) the first skew. The mirror transistors may have gate-to-source voltages with a second skew that is opposite in polarity with the first skew.

For some embodiments, the operations 900 may further include speeding up switching transitions of the first differential amplifier stage using capacitors coupled between the first differential amplifier stage and the pair of n-stage circuits.

For some embodiments, the operations 900 may further include sinking a small leakage current from (or providing a small leakage current to) the first differential amplifier stage to prevent main driver transistors in the first differential amplifier stage from completely switching off.

Although embodiments of the invention are described above for particular embodiments, many variations of the invention are possible. Additionally, features of the various embodiments may be combined in combinations that differ from those described above. Moreover, for clear and brief description, many descriptions of the systems and methods have been simplified. Many descriptions use terminology and structures of specific standards. However, the disclosed systems and methods are more broadly applicable.

Those of skill in the art will appreciate that the various illustrative logical blocks, modules, units, and algorithm steps described in connection with the embodiments disclosed herein can often be implemented as electronic hardware, computer software, or combinations of both. To clearly illustrate this interchangeability of hardware and software, various illustrative components, blocks, modules, and steps have been described above generally in terms of their functionality. Whether such functionality is implemented as hardware or software depends upon the particular constraints imposed on the overall system. Skilled persons can implement the described functionality in varying ways for each particular system, but such implementation decisions should not be interpreted as causing a departure from the scope of the invention. In addition, the grouping of functions within a unit, module, block, or step is for ease of description. Specific functions or steps can be moved from one unit, module, or block without departing from the invention.

The various illustrative logical blocks, units, steps, components, and modules described in connection with the embodiments disclosed herein can be implemented or performed with a processor, such as a general purpose processor, a digital signal processor (DSP), an application specific integrated circuit (ASIC), a field programmable gate array (FPGA) or other programmable logic device, discrete gate or transistor logic, discrete hardware components, or any combination thereof designed to perform the functions described herein. A general-purpose processor can be a microprocessor, but in the alternative, the processor can be any processor, controller, microcontroller, or state machine. A processor can also be implemented as a combination of computing devices, for example, a combination of a DSP and a microprocessor, a plurality of microprocessors, one or more microprocessors in conjunction with a DSP core, or any other such configuration.

The steps of a method and the processes of a block or module described in connection with the embodiments disclosed herein can be embodied directly in hardware, in a software module executed by a processor, or in a combination of the two. A software module can reside in RAM memory, flash memory, ROM memory, EPROM memory, EEPROM memory, registers, hard disk, a removable disk, a CD-ROM, or any other form of storage medium. An exemplary storage medium can be coupled to the processor such that the processor can read information from, and write information to, the storage medium. In the alternative, the storage medium can be integral to the processor. The processor and the storage medium can reside in an ASIC. Additionally, device, blocks, or modules that are described as coupled may be coupled via intermediary device, blocks, or modules. Similarly, a first device may be described a transmitting data to (or receiving from) a second device when there are intermediary devices that couple the first and second device and also when the first device is unaware of the ultimate destination of the data.

The above description of the disclosed embodiments is provided to enable any person skilled in the art to make or use the invention. Various modifications to these embodiments will be readily apparent to those skilled in the art, and the generic principles described herein can be applied to other embodiments without departing from the spirit or scope of the invention. Thus, it is to be understood that the description and drawings presented herein represent a presently preferred embodiment of the invention and are therefore representative of the subject matter that is broadly contemplated by the present invention. It is further understood that the scope of the present invention fully encompasses other embodiments that may become obvious to those skilled in the art and that the scope of the present invention is accordingly limited by nothing other than the appended claims.

What is claimed is:

1. An apparatus to provide low output common-mode voltage, the apparatus comprising:
a first differential amplifier stage configured to provide a differential output for the apparatus; and
a second differential amplifier stage configured to drive the first differential amplifier stage, the second differential amplifier stage comprising a pair of pre-driver amplifiers, a pair of n-stage circuits, and an input skew averaging circuit, wherein each of the pair of n-stage circuits is split into two half blocks and wherein the input skew averaging circuit is configured to suppress the output common-mode voltage by driving the two half blocks with complementary digital input to average out a skew in the pair of n-stage circuits.

2. The apparatus of claim 1, wherein each of the pair of n-stage circuits comprises:
an input transistor configuration; and
an inverter-based logic gate configured to drive the input transistor configuration.

3. The apparatus of claim 2, wherein the input skew averaging circuit comprises:
a pair of complementary transistor configurations, each configured to mirror one of the input transistor configurations in the pair of n-stage circuits; and
a pair of inverter-based logic gates configured to generate complementary inputs for the pair of complementary transistor configurations to average out the skew in gate-to-source voltages of the input transistor configurations.

4. The apparatus of claim 2, wherein the input transistor configuration comprises a PMOS transistor and an NMOS transistor.

5. The apparatus of claim 4, wherein the size of the PMOS transistor in the input transistor configuration is configured to be relatively small compared to the size of the NMOS transistor.

6. The apparatus of claim 1, further comprising:
a transconductance enhancement circuit configured with a pair of capacitors to speed up switching transitions of the first differential amplifier stage.

7. The apparatus of claim 1, wherein the first differential amplifier stage comprises a pair of main driver transistors configured as a common gate amplifier and wherein the second differential amplifier stage comprises a pair of input transistors configured as a common source amplifier in cascode with the common gate amplifier.

8. The apparatus of claim 7, further comprising:
a current sink circuit configured to sink a leakage current from the first differential amplifier stage to prevent the pair of main driver transistors in the first differential amplifier stage from completely switching off into a cut-off mode.

9. The apparatus of claim 8, wherein the current sink circuit comprises a pair of NMOS transistors, wherein gates of the NMOS transistors are coupled to outputs of the pair of pre-driver amplifiers, wherein drains of the NMOS transistors are coupled to differential inputs of the common gate amplifier, and wherein sources of the NMOS transistors are coupled to electrical ground.

10. The apparatus of claim 7, further comprising:
a pair of bias transistors configured in a cascode configuration to sink a bias current source and provide a bias voltage to a common gate node of the pair of main driver transistors in the common gate amplifier.

11. The apparatus of claim 7, further comprising:
a pair of capacitors coupled to gates of the pair of main driver transistors and to gates of the pair of input transistors.

12. The apparatus of claim 7, further comprising:
a pair of capacitors coupled to gates of the pair of main driver transistors and to inputs of the two half blocks.

13. The apparatus of claim 1, wherein each of the pair of pre-driver amplifiers comprises a programmable inverter-based logic device configured to control rising and falling edges of a gate-to-source voltage of each of the pair of n-stage circuits.

14. The apparatus of claim 13, wherein the programmable inverter-based logic device comprises:
a PMOS transistor; and
a plurality of parallel NMOS transistors, each NMOS transistor coupled to a switch to allow each NMOS transistor to be programmably switched in.

15. A method for suppressing an output common-mode voltage in a driver, the method comprising:
driving a first differential amplifier stage using a second differential amplifier stage comprising a pair of pre-driver amplifiers, a pair of n-stage circuits, and an input skew averaging circuit, wherein each of the pair of n-stage circuits is split into two half blocks; and
performing input skew averaging to suppress the output common-mode voltage by driving the two half blocks with complementary digital inputs to average out a first skew in gate-to-source voltages of the pair of n-stage circuits.

16. The method of claim 15, wherein performing input skew averaging further comprises:
combining outputs of mirror transistors, which mirror transistors in the pair of n-stage circuits, with outputs of the pair of n-stage circuits to remove or decrease the first skew, wherein the mirror transistors have gate-to-source voltages with a second skew that is opposite in polarity with the first skew.

17. The method of claim 15, further comprising:
speeding up switching transitions of the first differential amplifier stage using capacitors coupled between the first differential amplifier stage and the pair of n-stage circuits.

18. The method of claim 15, further comprising:
sinking a leakage current from the first differential amplifier stage to prevent main driver transistors in the first differential amplifier stage from completely switching off.

19. An apparatus for suppressing output common-mode voltage in a driver, comprising:
means for driving a differential amplifier stage, wherein the means for driving comprises a pair of pre-driver amplifiers and a pair of n-stage circuits, wherein each of the pair of n-stage circuits is split into two half blocks; and
means for performing input skew averaging to suppress the output common-mode voltage by driving the two half blocks with complementary digital inputs to average out a first skew in gate-to-source voltages of the pair of n-stage circuits.

20. The apparatus of claim 19, wherein the means for performing input skew averaging further comprises:
means for combining outputs of mirror transistors, which mirror transistors in the pair of n-stage circuits, with outputs of the pair of n-stage circuits to remove or decrease the first skew, wherein the mirror transistors have gate-to-source voltages with a second skew that is opposite in polarity with the first skew.

21. The apparatus of claim 19, further comprising:
means for speeding up switching transitions of the differential amplifier stage coupled between the differential amplifier stage and the pair of n-stage circuits.

22. The apparatus of claim 19, further comprising:
means for sinking a leakage current from the differential amplifier stage to prevent main driver transistors in the differential amplifier stage from completely switching off.
